(19) United States
(12) Patent Application Publication
(10) Pub. No.: US 2026/0013188 A1
(43) Pub. Date: Jan. 8, 2026

(54) SEMICONDUCTOR DEVICE INCLUDING CHANNEL LAYER

(71) Applicant: Samsung Electronics Co., LTD., Suwon-si, Gyeonggi-do (KR)

(72) Inventors: Taejin PARK, Suwon-si, Gyeonggi-do (KR); Hosang LEE, Suwon-si, Gyeonggi-do (KR); Kyusul PARK, Suwon-si, Gyeonggi-do (KR); Sungsoo YIM, Suwon-si, Gyeonggi-do (KR)

(21) Appl. No.: 18/638,769

(22) Filed: Apr. 18, 2024

(30) Foreign Application Priority Data
Jun. 14, 2023 (KR) 10-2023-0076329

(51) Int. Cl. H10D 62/17; H10B 12/00; H10D 64/27

(52) U.S. Cl. CPC H10D 62/292; H10B 12/05; H10B 12/315; H10B 12/482; H10B 12/488; H10B 12/50; H10D 64/514

(57) ABSTRACT

A semiconductor device includes a bit line extending in a first direction; a word line extending in a second direction crossing the first direction, the word line being at a level higher than a level of the bit line; a channel layer on the bit line, the channel layer including a vertical portion at least partially at the same level as the word line, and an extension portion extending from an upper region of the vertical portion; a gate dielectric layer at least partially between the vertical portion and the word line; and an upper conductive pattern on the extension portion, wherein the extension portion includes a first region vertically overlapping the vertical portion and a second region not vertically overlapping the vertical portion, and the upper conductive pattern has a side surface vertically aligned with a side surface of the extension portion.

### CROSS-REFERENCE TO RELATED APPLICATION(S)

This application claims the benefit under 35 USC 119(a) of Korean Patent Application No. 10-2023-0076329 filed on Jun. 14, 2023, in the Korean Intellectual Property Office, the entire disclosure of which is incorporated herein by reference for all purposes.

### BACKGROUND

### 1. Field

Embodiments relate to a semiconductor device including a channel layer.

### 2. Description of the Related Art

Reducing the size of elements constituting semiconductor devices and improving performance thereof has been considered.

### SUMMARY

The embodiments may be realized by providing a semiconductor device including a bit line extending in a first direction; a word line extending in a second direction crossing the first direction, the word line being at a level higher than a level of the bit line; a channel layer on the bit line, the channel layer including a vertical portion at least partially at the same level as the word line, and an extension portion extending from an upper region of the vertical portion; a gate dielectric layer at least partially between the vertical portion and the word line; and an upper conductive pattern on the extension portion, wherein the extension portion includes a first region vertically overlapping the vertical portion and a second region not vertically overlapping the vertical portion, and the upper conductive pattern has a side surface vertically aligned with a side surface of the extension portion.

The embodiments may be realized by providing a semiconductor device including a bit line; a first channel layer and a second channel layer spaced apart from each other on the bit line; a first word line and a second word line spaced apart from each other on the bit line, and respectively including a portion between the first and second channel layers; an intermediate layer connected to the first and second channel layers and the bit line; a first gate dielectric layer at least partially between the first channel layer and the first word line; a second gate dielectric layer at least partially between the second channel layer and the second word line; a first upper conductive pattern on the first channel layer and connected to the first channel layer; and a second upper conductive pattern on the second channel layer and connected to the second channel layer.

The embodiments may be realized by providing a semiconductor device including a bit line; an insulating structure on the bit line and having an opening exposing the bit line; a structure at least partially in the opening; and upper conductive patterns on the structure, wherein the structure includes a first channel layer and a second channel layer spaced apart from each other in the opening; a first word line and a second word line spaced apart from each other in the opening and respectively including a portion between the first and second channel layers; an intermediate insulating pattern in the opening and between the first and second word lines and covering upper surfaces of the first and second word lines; a first gate dielectric layer at least partially between the first channel layer and the first word line; and a second gate dielectric layer at least partially between the second channel layer and the second word line, each of the first and second channel layers includes a vertical portion in the opening and an extension portion extending from an upper region of the vertical portion, the upper conductive patterns include a first upper conductive pattern on the extension portion of the first channel layer and a second upper conductive pattern on the extension portion of the second channel layer, the first upper conductive pattern has a side surface vertically aligned with a side surface of the extension portion of the first channel layer, and the second upper conductive pattern has a side surface vertically aligned with a side surface of the extension portion of the second channel layer.

### BRIEF DESCRIPTION OF DRAWINGS

Features will be apparent to those of skill in the art by describing in detail exemplary embodiments with reference to the attached drawings in which:

FIGS. 1, 2A, 2B, and 2C are diagrams schematically illustrating a semiconductor device according to an example embodiment;

FIG. 3 is a cross-sectional view schematically illustrating a modified example of a semiconductor device according to an example embodiment;

FIG. 4 is a cross-sectional view schematically illustrating a modified example of a semiconductor device according to an example embodiment;

FIG. 5 is a cross-sectional view schematically illustrating a modified example of a semiconductor device according to an example embodiment;

FIG. 6 is a cross-sectional view schematically illustrating a modified example of

a semiconductor device according to an example embodiment;

FIG. 7 is a cross-sectional view schematically illustrating a modified example of a semiconductor device according to an example embodiment;

FIG. 8 is a cross-sectional view schematically illustrating a modified example of a semiconductor device according to an example embodiment;

FIG. 9 is a cross-sectional view schematically illustrating a modified example of a semiconductor device according to an example embodiment;

FIG. 10 is a cross-sectional view schematically illustrating a modified example of a semiconductor device according to an example embodiment;

FIG. 11A is a cross-sectional view schematically illustrating a modified example of a semiconductor device according to an example embodiment;

FIG. 11B is a cross-sectional view schematically illustrating a modified example of a semiconductor device according to an example embodiment;

FIG. 11C is a cross-sectional view schematically illustrating a modified example of a semiconductor device according to an example embodiment;

FIG. 11D is a cross-sectional view schematically illustrating a modified example of a semiconductor device according to an example embodiment;

FIG. 12A is a cross-sectional view schematically illustrating a modified example of a semiconductor device according to an example embodiment;

FIG. 12B is a cross-sectional view schematically illustrating a modified example of a semiconductor device according to an example embodiment;

FIG. 12C is a cross-sectional view schematically illustrating a modified example of a semiconductor device according to an example embodiment; and

FIGS. 13 to 23C are diagrams illustrating stages in a method of forming a semiconductor device according to an example embodiment.

### DETAILED DESCRIPTION

Hereinafter, terms such as “upper”, “middle”, “lower” and the like may be replaced with other terms, such as “first”, “second”, “third” and the like to describe the elements of the specification. Terms such as “first”, “second”, “third” and the like may be used to describe various elements, but the elements are not limited by the terms, e.g., the terms are not intended to imply or require sequential inclusion, and a “first element” may be referred to as a “second element”. As used herein, the term “or” is not necessarily an exclusive term, e.g., “A or B” would include A, B, or A and B.

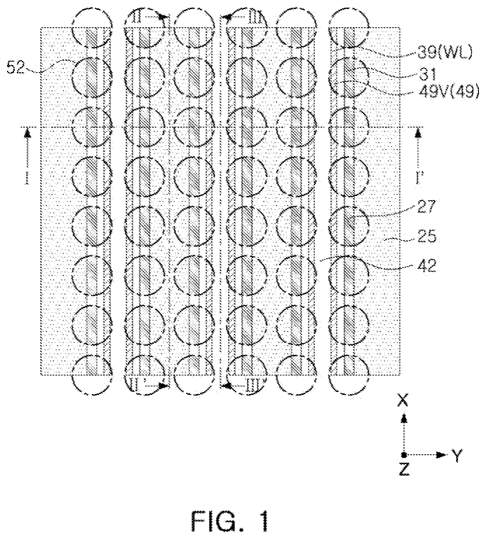

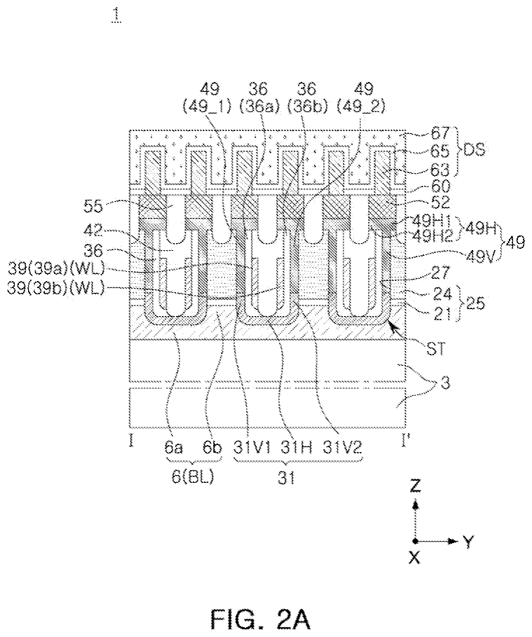

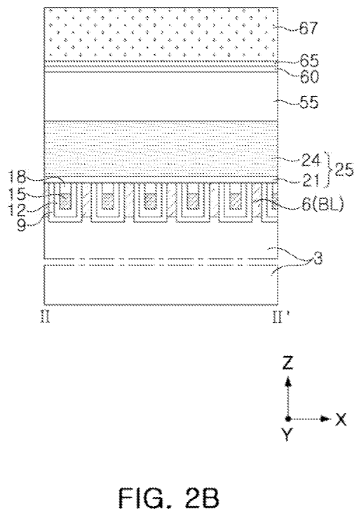

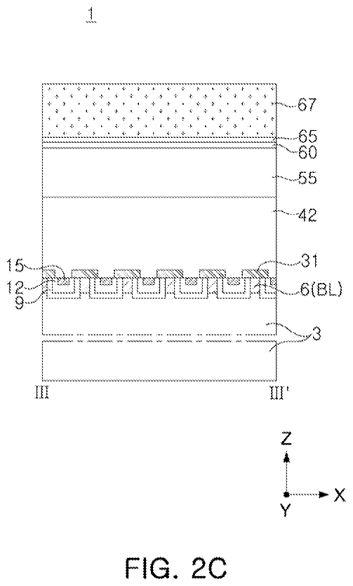

First, illustrative examples of a semiconductor device according to an example embodiment will be described with reference to FIGS. 1, 2A, 2B, and 2C. In FIGS. 1A to 2C, FIG. 1 is a top view schematically illustrating a semiconductor device according to an example embodiment, FIG. 2A is a cross-sectional view schematically illustrating a region taken along line I-I′ of FIG. 1, FIG. 2B is a cross-sectional view schematically illustrating a region taken along line II-II′ in FIG. 1, FIG. 2C is a cross-sectional view schematically illustrating a region taken along line III-III′ in FIG. 1.

Referring to FIGS. 1, 2A, 2B, and 2C, a semiconductor device 1 according to an example embodiment may include a lower structure 3 and first conductive lines 6 on the lower structure 3.

The lower structure 3 may include an insulating layer.

The lower structure 3 may include a peripheral circuit structure including a peripheral circuit.

Each of the first conductive lines 6 may have a line shape extending in the first direction Y. The first conductive lines 6 may be spaced apart from each other in a second direction X, perpendicular to the first direction Y.

The first direction (Y) and the second direction (X) may be parallel to the upper surface of the lower structure (3).

The first conductive lines 6 may be bit lines BL.

Each of the first conductive lines 6 may include doped polysilicon, metal,

conductive metal nitride, metal-semiconductor compound, conductive metal oxide, conductive graphene, carbon nanotube, or combinations thereof. In an implementation, each of the conductive lines 6 may include, e.g., doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or combinations thereof. Each of the first conductive lines 6 may include a single layer or multiple layers of the aforementioned materials.

The semiconductor device 1 may further include shield structures 8 between the first conductive lines 6. The first conductive lines 6 and the shield structures 8 may be alternately and repeatedly arranged in the second direction (X).

Each of the shield structures 8 may include a conductive shield pattern 15. Each of the conductive shield patterns 15 may have a line shape extending (e.g., lengthwise) in the first direction Y. The conductive shield patterns 15 may be parallel to the conductive lines 6. The conductive shield patterns 15 may be spaced apart from the conductive lines 6.

Each of the shield structures 8 may further include a first insulating layer 9 covering the side surface and bottom surface of the conductive shield pattern 15, a second insulating layer 12 between the first insulating layer 9 and the conductive shield pattern 15, and a third insulating layer 18 on the conductive shield pattern 15.

The semiconductor device 1 may include an insulating structure 25 having an opening 27 on the conductive lines 6 and the shield structures 8.

The insulating structure 25 may include an etch stop layer 21 and an interlayer insulating layer 24 sequentially stacked. The interlayer insulating layer 24 may have a thickness smaller or thinner than that of the etch stop layer 21. The etch stop layer 21 may include a material different from that of the interlayer insulating layer 24. In an implementation, the interlayer insulating layer 24 may be formed of silicon oxide or low-K dielectric, and the etch stop layer 21 may be formed of silicon nitride or a high-K dielectric.

In an implementation, the ‘low dielectric’ may be a dielectric having a dielectric constant smaller than that of silicon oxide, and a ‘high dielectric’ may be a dielectric having a dielectric constant greater than that of silicon oxide. The opening 27 may have a linear shape extending in the second direction (X). The first conductive lines 6 and the shield structures 8 may be exposed through the opening 27.

The semiconductor device 1 may further include a structure ST. At least a portion of the structure ST may be in the opening 27.

Each of the first conductive lines 6 may include a first region 6a vertically overlapping the structure ST and a second region 6b vertically overlapping the insulating structure 25. In each of the first conductive lines 6, the first region 6a may contact the structure ST, the second region 6b may contact the insulating structure 25. In each of the first conductive lines 6, the thickness of the second region 6b may be greater than that of the first region 6a. In each of the first conductive lines 6, the upper surface of the second region 6b may be at a higher level than the upper surface of the first region 6a.

The structure ST may further include channel layers 49, second conductive lines 39, gate dielectric layers 36, an intermediate layer 31, and an intermediate insulating pattern 42.

The channel layers 49 may include a material usable as a channel of a transistor, e.g., a semiconductor material. In an implementation, each of the channel layers 49 may include an oxide semiconductor layer or a two-dimensional (2D) material layer that may be used as a channel region of a transistor.

In an implementation, the oxide semiconductor layer may include, e.g., indium gallium zinc oxide (IGZO). In an implementation, the oxide semiconductor layer may include, e.g., indium tungsten oxide (ITO), indium tin gallium oxide (ITGO), indium aluminum zinc oxide (IAZO), indium gallium oxide (IGO), indium tin zinc oxide (ITZO), zinc zinc oxide (ZTO), tin oxide, indium zinc oxide (IZO), zinc oxide (ZnO), indium gallium silicon oxide (IGSO), indium oxide (InO), tin oxide (SnO), titanium oxide (TiO), zinc oxynitride (ZnON), Magnesium Zinc Oxide (MgZnO), Indium Zinc Oxide (InZnO), Indium Gallium Zinc Oxide (InGaZnO), Zirconium Indium Zinc Oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc Oxide (SiInZnO), Zinc Tin Oxide (ZnSnO), Aluminum Zinc Tin Oxide (AlZnSnO), Gallium Zinc Tin Oxide (GaZnSnO), Zirconium Zinc Tin Oxide (ZrZnSnO), or Indium Gallium Silicon Oxide (InGaSiO).

The 2D material layer may include a transition metal dichalcogenide material layer (TMD material layer), a black phosphorous material layer, or a hexagonal boron-nitride material layer (hBN material layer). In an implementation, the two-dimensional material layer may include, e.g., BiOSe, CrI₃, WSe₂, CuSe₂, MoS₂, TaS, WS, CuS₂, SnSe, ReS, β-SnTe, MnO, AsS, P(black), InSe, h-BN, GaSe, GaN, SrTiO, MXene, or Janus 2D materials, which are capable of forming two-dimensional matter.

The channel layers 49 are materials that may be used as a channel of a transistor. In an implementation, the channel layers 49 may be formed of single crystal silicon or polysilicon.

When viewed from a top view as illustrated in FIG. 1, the vertical portions ( 49V of FIG. 2A) of the channel layers 49 may be sequentially arranged while being spaced apart from each other along the second direction X, and may be spaced apart from each other in the first direction (Y). When viewed from the top view as in FIG. 1, each of the vertical portions ( 49V in FIG. 2A) of the channel layers 49 may have a bar shape extending in the second direction X.

Lower ends of the channel layers 49 may be at a higher level than lower ends of the second conductive lines 39. The channel layers 49 may include a first channel layer 49_1 and a second channel layer 49_2 spaced apart from each other. Each of the first and second channel layers 49_1 and 49_2 may include a vertical portion 49V extending in the vertical direction Z and an extension portion 49H extending from an upper region of the vertical portion 49V.

In each of the first and second channel layers 49_1 and 49_2, the extension portion 49H may include an area that vertically overlaps the vertical portion 49V and an area that does not vertically overlap the vertical portion 49V.

The second conductive lines 39 may be on the first conductive lines 6 and the shield structure 8. A portion of each of the second conductive lines 39 may be at the same level as a portion of each of the vertical portions 49V of the channel layers 49.

Each of the second conductive lines 39 may extend in the second direction X crossing the first direction Y. The second direction X may be perpendicular to the first direction Y. The second conductive lines 39 may be parallel to each other.

The second conductive lines 39 may be word lines WL. The second conductive lines 39 may include, e.g., doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or combination thereof. Each of the second conductive lines 39 may include a single layer or multiple layers of the aforementioned materials.

Hereinafter, the first conductive lines 6 will be referred to as bit lines and described, and the second conductive lines 39 will be referred to as word lines. Also, hereinafter, one bit line among the bit lines 6 will be mainly described.

The word lines 39 may include a first word line 39a and a second word line 39b spaced apart from each other and adjacent to each other. The first and second word lines 339a and 39b may include portions between the first and second channel layers 49_1 and 49_2, respectively.

Upper ends of the first and second word lines 339a and 39b may be at a lower level than upper ends of the vertical portions 49V of the first and second channel layers 49_1 and 49_2.

In an implementation, lower ends of the first and second word lines 339a and 39b may be at a lower level than lower ends of the vertical portions 49V of the first and second channel layers 49_1 and 49_2.

In an implementation, lower ends of the first and second word lines 39a and 39b may be at the same level as or higher than the upper surface of the second region 6b of the bit line 6.

In an implementation, lower ends of the first and second word lines 39a and 39b may be at a level lower than an upper surface of the second region 6b of the bit line 6.

In an implementation, lower ends of the first and second word lines 39a and 39b may be at a level lower than the upper surface of the etch stop layer 21.

The intermediate insulating pattern 42 may be between the first and second word lines 39a and 39b and cover upper portions of the first and second word lines 39a and 39b. The first and second word lines 39a and 39b may be spaced apart from each other with the intermediate insulating pattern 42 therebetween. The intermediate insulating pattern 42 may be between the vertical portions 49V of the first and second channel layers 49_1 and 49_2, and the first and second channel layers 49_1 and 49_2 may be at a lower level than the extension portion 49H. The intermediate insulating pattern 42 may include silicon oxide or a low-K dielectric having a dielectric constant smaller than that of silicon oxide.

The intermediate layer 31 may include a first intermediate portion 31V1 vertically overlapping the vertical portion 49V of the first channel layer 49_1, and a second intermediate portion 31V2 vertically overlapping the vertical portion 49V of the second channel layer 49_2. The intermediate layer 31 may further include a connection portion 31H extending from lower regions of the first and second intermediate portions 31V1 and 31V2.

The intermediate layer 31 may contact the first and second channel layers 49_1 and 49_2 and the bit line 6. Upper ends of the first and second intermediate portions 31V1 and 31V2 of the intermediate layer 31 may contact (e.g., directly contact) lower surfaces of the first and second channel layers 49_1 and 49_2. The upper ends of the first and second intermediate portions 31V1 and 31V2 of the intermediate layer 31 may be at a higher level than lower ends of the first and second word lines 39a and 39b. The first and second channel layers 49_1 and 49_2 may be spaced apart from the bit line 6 with the intermediate layer 31 therebetween.

A lower surface of the intermediate layer 31 may contact an upper surface of the first region 6a of the bit line 6. It may be at a level lower than the upper surface of the second region 6b of the bit line 6.

The intermediate layer 31 may include a conductive material layer. In an implementation, the intermediate layer 31 may include a metal nitride, e.g., TiN. In an implementation, the intermediate layer 31 may include another conductive material that may replace TiN, e.g., WN or TaN.

The gate dielectric layers 36 may include the first gate dielectric layer 36a and the second gate dielectric layer 36b.

At least a portion of the first gate dielectric layer 36a may be between the first channel layer 49_1 and the first word line 39a. The first gate dielectric layer 36a may include a portion extending upwardly and a portion extending downwardly from a portion between the first channel layer 49_1 and the first word line 39a.

The first gate dielectric layer 36a may extend between the first word line 39a and the intermediate layer 31 from a portion between the first channel layer 49_1 and the first word line 39a. A portion of the first gate dielectric layer 36a may be between a lower surface of the first word line 39a and the connection portion 31H of the intermediate layer 31. The first gate dielectric layer 36a may extend from a portion between the first channel layer 49_1 and the first word line 39a to between the intermediate insulating pattern 42 and the vertical portion 49V of the first channel layer 49_1.

The second gate dielectric layer 36b may extend between the second word line 39b and the intermediate layer 31 from a portion between the second channel layer 49_2 and the second word line 39b. A portion of the second gate dielectric layer 36b may be between the lower surface of the second word line 39b and the connection portion 31H of the intermediate layer 31. The second gate dielectric layer 36b may extend between the intermediate insulating pattern 42 and the vertical portions 49V of the second channel layer 49_2 from a portion between the second channel layer 49_2 and the second word line 39b.

Each of the extension portions 49H of the first and second channel layers 49_1 and 49_2 may include a first extension region 49H1 and a second extension region 49H2.

The first extension region 49H1 of the extension portion 49H of the first channel layer 49_1 may contact the upper surface of the insulating structure 25, and the second extension region 49H2 of the extension portion 49H of the first channel layer 49_1 may contact the upper surface of the first gate dielectric layer 36a and the upper surface of the intermediate insulating pattern 42. The first extension region 49H1 of the extension portion 49H of the second channel layer 49_2 may contact the upper surface of the insulating structure 25, and the second extension region 49H2 of the extension portion 49H of the second channel layer 49_2 may contact the upper surface of the second gate dielectric layer 36b and the upper surface of the intermediate insulating pattern 42.

The second extension region 49H2 of the extension portion 49H of the first channel layer 49_1 may vertically overlap the first word line 39a, and the second extension region 49H2 of the extension portion 49H of the second channel layer 49_2 may vertically overlap the second word line 39b.

Each of the gate dielectric layers 36 may include silicon oxide or a high-K dielectric. The high dielectric may be a dielectric having a dielectric constant higher than that of silicon oxide. The high-K dielectric may include a metal oxide or a metal oxynitride. In an implementation, the high dielectric may be made of HfO₂, HfSiO, HfSiON, HfTaO, HfTiO, HfZrO, ZrO₂, Al₂O₃, or combinations thereof. Each of the gate dielectric layers 36 may be formed of a single layer or multiple layers of the materials described above.

The semiconductor device 1 may further include upper conductive patterns 52 on the channel layers 49. The upper conductive patterns 52 may contact the channel layers 49. The upper conductive patterns 52 may contact upper surfaces of the extension portions 49H of the channel layers 49. The upper conductive patterns 52 may be vertically aligned with the extension portions 49H of the channel layers 49. The upper conductive patterns 52 may have side surfaces vertically aligned with side surfaces of the extension portions 49H of the channel layers 49.

The extension portions 49H of the channel layers 49 may increase a contact area between the channel layers 49 and the upper conductive patterns 52. In an implementation, by increasing the contact area between the upper conductive patterns 52 and the channel layers 49c, contact resistance between the upper conductive patterns 52a and the channel layers 49c may be reduced. Accordingly, the electrical characteristics of the semiconductor device may be improved.

The upper conductive patterns 52 may include a first upper conductive pattern 52a on the extension portion 49H of the first channel layer 49_1, and a second upper conductive pattern 52b on the extension portion 49H of the second channel layer 49_2. The first upper conductive pattern 52a may have a side surface vertically aligned with a side surface of the extension portion 49H of the first channel layer 49_1. The second upper conductive pattern 52b may have a side surface vertically aligned with a side surface of the extension portion 49H of the second channel layer 49_2.

The semiconductor device 1 may further include insulating separation patterns 55 on side surfaces of the extension portions 49H and the upper conductive patterns 52 that are sequentially stacked and vertically aligned. The insulating separation pattern 55 may pass between the upper conductive patterns 52 and extend downward. The insulating separation pattern 55 may include a portion extending into the interlayer insulating layer 24 and a portion extending into the intermediate insulating pattern 42. A lower end of the insulating separation pattern 55 may be at a lower level than the extension portions 49H of the channel layers 49. An upper surface of the insulating separation pattern 55 may be coplanar with upper surfaces of the upper conductive patterns 52.

The semiconductor device 1 may further include an etch stop layer 60 on the upper conductive patterns 52 and the insulating separation pattern 55. The etch stop layer 60 may include an insulating material, e.g., silicon nitride, SiBN, SiCN, or an insulating metal oxide.

The semiconductor device 1 may further include a data storage structure DS. The data storage structure DS may include first electrodes 63 penetrating the etch stop layer 60 and electrically connected to the upper conductive patterns 52, and a dielectric layer 65 covering the first electrodes 63 and the etch stop layer 60, and a second electrode 67 covering the dielectric layer 65.

In an implementation, the data storage structure DS may be a capacitor for storing data in DRAM. In an implementation, the dielectric layer 65 of the data storage structure DS may be a capacitor dielectric layer of a DRAM. The dielectric layer 65 may include a high dielectric, silicon oxide, silicon nitride, silicon oxynitride, or combinations thereof.

In an implementation, the data storage structure DS may be a capacitor structure for storing DRAM and other memory information. In an implementation, the data storage structure DS may be between the first and second electrodes 63 and 67, and may be a capacitor of a ferroelectric memory (FeRAM) including a dielectric layer 65 including a ferroelectric layer or an anti-ferroelectric layer.

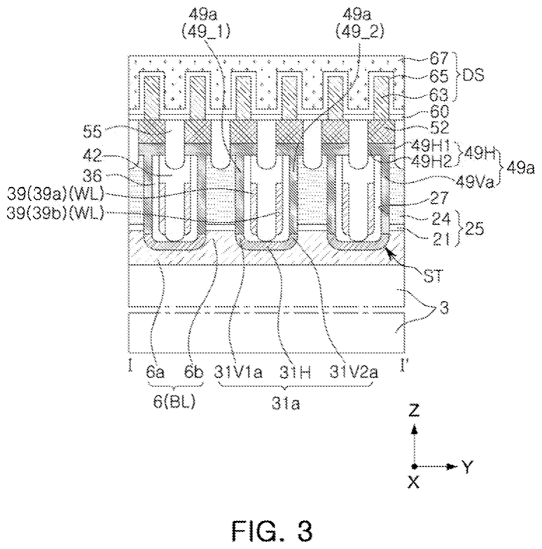

Various modified examples of the elements of the above-described embodiment will be described. Various modified examples of the elements of the above-described embodiment described below will be described focusing on the modified or replaced elements. In this case, the elements described above may be directly cited without separate detailed description, or the description may be omitted. In addition, elements that may be modified or replaced described below will be described with reference to the drawings, and elements that may be modified or replaced may be combined with each other or with the elements described above to form a semiconductor device according to an example embodiment. FIGS. 3, 4, 5, 6, 7, 8, 9, 10, 11A, 11B, 11C, 11D, 12A, 12B, and 12C are cross-sectional views taken along line I-I′ in FIG. 1, to describe various modifications according to the example embodiments.

In an implementation, referring to FIG. 3, the channel layers 49 in FIG. 2A may instead be channel layers 49a having lower ends at a lower level than the lower surface of the interlayer insulating layer 24. In an implementation, the vertical portions 49V of the channel layers 49 in FIG. 2A may be vertical portions 49Va having lower ends disposed at a lower level than the lower surface of the interlayer insulating layer 24. Accordingly, the channel layers 49a may include the vertical portions 49Va and the extension portions 49H as illustrated in FIG. 2A.

The intermediate layer 31 in FIG. 2A may instead be an intermediate layer 31a having an upper end at a lower level than the lower surface of the interlayer insulating layer 24. In an implementation, the first and second intermediate portions 31V1 and 31V2 of the intermediate layer 31 in FIG. 2A may be first and second intermediate portions 31V1a and 31V2 having an upper end at a lower level than the lower surface of the interlayer insulating layer 24. Accordingly, the intermediate layer 31a may include the first and second intermediate portions 31V1a and 31V2 and the connection portions 31H as illustrated in FIG. 2A.

In an implementation, lower ends of the vertical portions 49Va may be at a lower level than a lower surface of the etch stop layer 21. Accordingly, the vertical portions 49Va of the channel layers 49a may contact the intermediate layer 31 and the bit line 6.

In an implementation, lower ends of the vertical portions 49Va may be at substantially the same level as lower ends of the word lines 39.

In an implementation, lower ends of the vertical portions 49Va may be at a lower level than lower ends of the word lines 39.

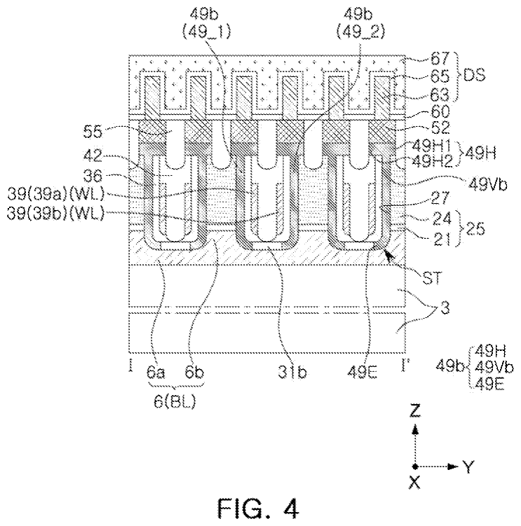

In an implementation, referring to FIG. 4, the channel layers 49 in FIG. 2A may instead be channel layers 49b having lower ends positioned at a lower level than lower ends of the word lines 39. The vertical portions 49V in FIG. 2A may be vertical portions 49Vb extending downwardly and contacting the bit line 6. Each of the channel layers 49b may further include a lower extension portion 49E that extends while being bent from the vertical portion 49Vb. Accordingly, each of the channel layers 49b may include the vertical portion 49Vb and the lower extension portion 49E along with the extension portion 49H in FIG. 2A. The channel layers 49b may include a first channel layer 49_1 and a second channel layer 49_2 spaced apart from each other.

The intermediate layer 31 in FIG. 2A may instead be an intermediate layer 31b between the lower extension portion 49E of the first channel layer 49_1 and the lower extension portion 49E of the second channel layer 49_2. The intermediate layer 31 may vertically overlap the word columns 39.

In an implementation, the intermediate layer 31 may include a conductive material layer.

In an implementation, the intermediate layer 31 may include an insulating material layer.

In an implementation, the intermediate layer 31 may be an empty space such as an air gap.

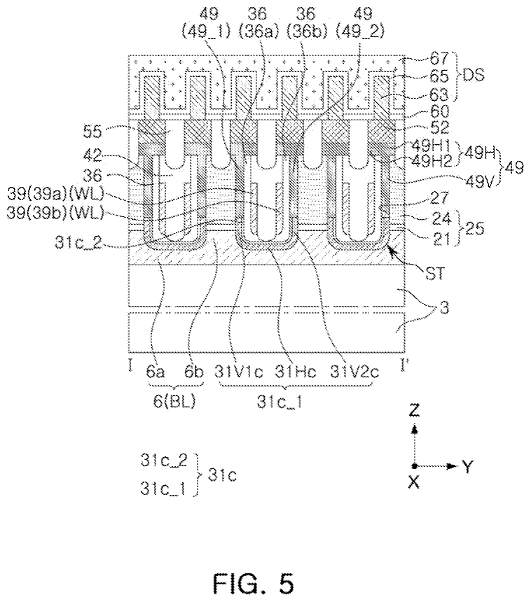

In an implementation, referring to FIG. 5, the intermediate layer 31 in FIG. 2A may instead be an intermediate layer 31c including a first intermediate material layer 31c_1 and a second intermediate material layer 31c_2 on the first intermediate material layer 31c_1. The first intermediate material layer 31c_1 may include a conductive material layer, e.g., TiN, WN, or TaN. The second intermediate material layer 31c_2 may include an oxide of a conductive material of the first intermediate material layer 31c_1, e.g., TiON. In an implementation, the second intermediate material layer 31c_2 may be an insulating material layer. The first intermediate material layer 31c_1 may include the first intermediate portion 31V1 and the second intermediate portion 31V2 described in FIG. 2A, and a first intermediate portion 31V1c, a second intermediate portion 31V2c, and a connection portion 31Hc corresponding to the connection portion 31H, respectively.

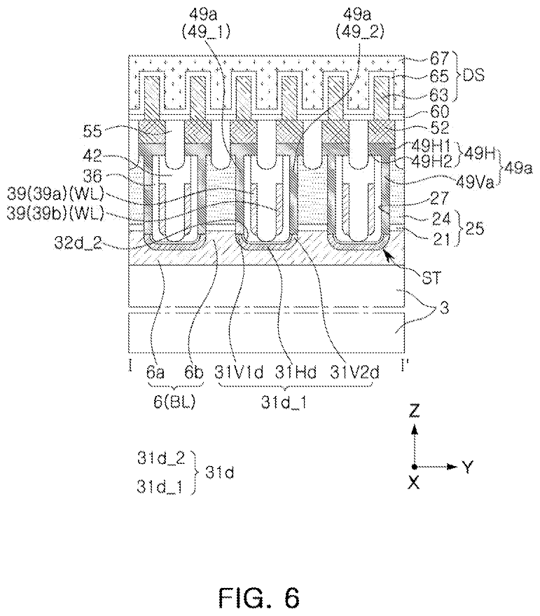

In an implementation, referring to FIG. 6, the intermediate layer 31a in FIG. 3 may instead be an intermediate layer 31d including a first intermediate material layer 31c_1 and a second intermediate material layer 31c_2 on the first intermediate material layer 31c_1. As illustrated in FIG. 5, the intermediate layer 31d may include a first intermediate material layer 31d_1 and a second intermediate material layer 31d_2 on the first intermediate material layer 31d_1. The first and second intermediate material layers 31d_1 and 31d_2 may be formed of the same material as the first and second intermediate material layers 31c_1 and 31c_2 in FIG. 5.

The first intermediate material layer 31d_1 may include the first intermediate portion 31V1a and the second intermediate portion 31V2a described in FIG. 3, and a first intermediate portion 31V1d, a second intermediate portion 31V2d, and a connection portion 31Hd corresponding to the connection portion 31H, respectively.

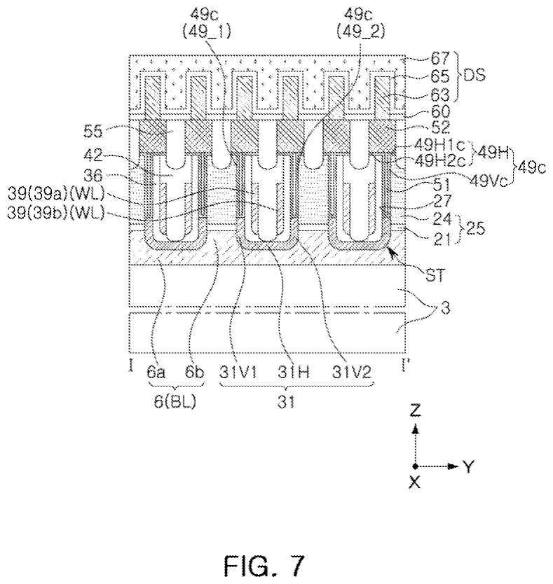

In an implementation, referring to FIG. 7, the channel layers 49 in FIG. 2A may instead be channel layers 49c having an inner region 51. Each of the channel layers 49c may include a vertical portion 49c covering the lower surface and both side surfaces of the inner region 51 and an extension region 49Hc extending from the vertical portion 49c.

In each of the channel layers 49c, the extension region 49Hc may include a first extension region 49H1c and a second extension region 49H2c disposed at positions corresponding to the first extension region 49H1 and the second extension region 49H2 in FIG. 2A, respectively.

In an implementation, the inner region 51 may include an insulating material, e.g., silicon oxide or a low dielectric material.

In an implementation, the inner region 51 may be an empty space such as a void or air gap.

The upper conductive patterns 52 described above with reference to FIG. 2A may cover upper surfaces of the channel layers 49c and upper portions of the internal space.

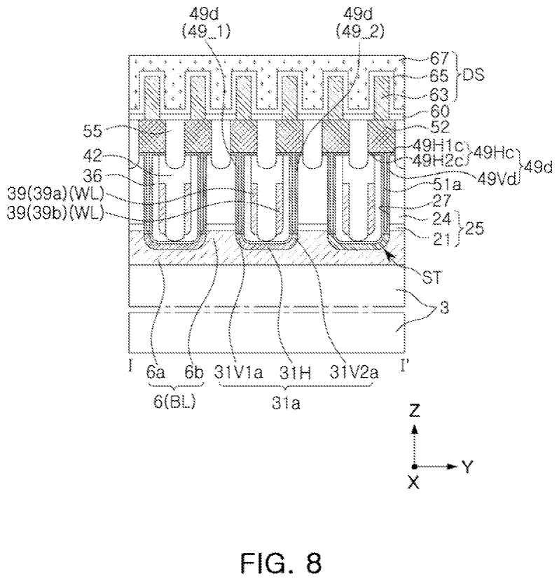

In an implementation, referring to FIG. 8, the channel layers 49a in FIG. 3 may instead be channel layers 49d having an inner region 51a. Each of the channel layers 49d may include a vertical portion 49Vd covering the lower surface and both side surfaces of the inner region 51a, and an extension region 49Hc extending from the vertical portion 49Vd. In each of the channel layers 49d, the extension region 49Hc may be the same as the extension region 49Hc in FIG. 7. Like the internal region 51 in FIG. 7, the inner region 51a may be an insulating material such as silicon oxide or a low dielectric material, or an empty space such as a void.

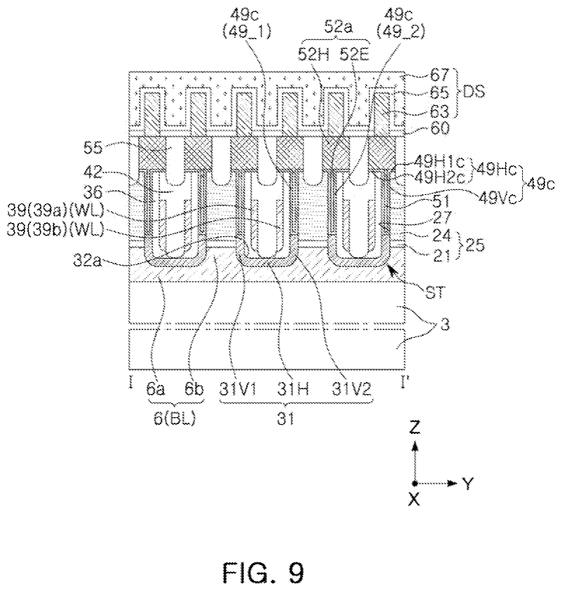

In an implementation, referring to FIG. 9, each of the upper conductive patterns 52 in FIG. 8 may instead be an upper conductive pattern 52a including a horizontal portion 59H covering the upper surface of the extension region 49Hc of the channel layer 49c and an extension portion 52E extending from the horizontal portion 59P into the inner region 51.

In each of the upper conductive patterns 52a, the lower end of the extension portion 52E may be at a level lower than the upper end of the vertical portion 49Vc and the extension portion 49Hc.

In each of the upper conductive patterns 52a, side surfaces of the extension portion 52E may contact the vertical portion 49Vc of the channel layer 49c. In an implementation, by increasing the contact area between the upper conductive pattern 52a and the channel layer 49c, contact resistance between the upper conductive pattern 52a and the channel layer 49c may be reduced. Accordingly, the electrical characteristics of the semiconductor device may be improved.

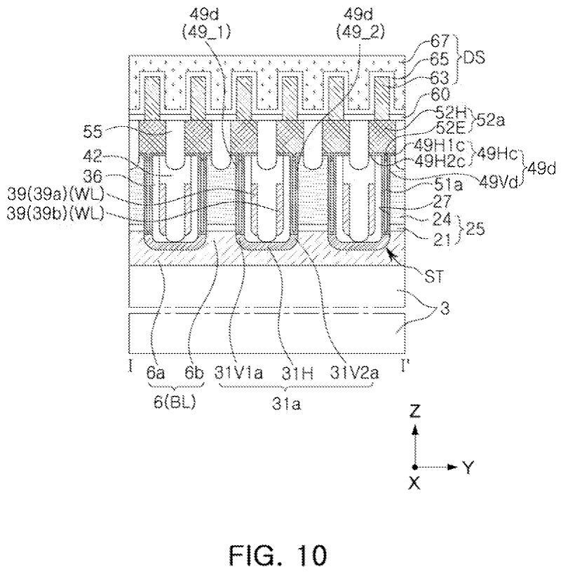

In an implementation, referring to FIG. 10, each of the upper conductive patterns 52 in FIG. 9 may instead be an upper conductive pattern 52a including a horizontal portion 59H covering the upper surface of the extension region 49Hc of the channel layer 49c and an extension portion 52E extending from the horizontal portion 59P into the inner region 51.

In each of the upper conductive patterns 52a, the lower end of the extension portion 52E may be at a level lower than the upper end of the vertical portion 49Vc and the extension portion 49Hc.

In each of the upper conductive patterns 52a, side surfaces of the extension portion 52E may contact the vertical portion 49Vc of the channel layer 49c. In an implementation, by increasing the contact area between the upper conductive pattern 52a and the channel layer 49c, contact resistance between the upper conductive pattern 52a and the channel layer 49c may be reduced. Accordingly, the electrical characteristics of the semiconductor device may be improved.

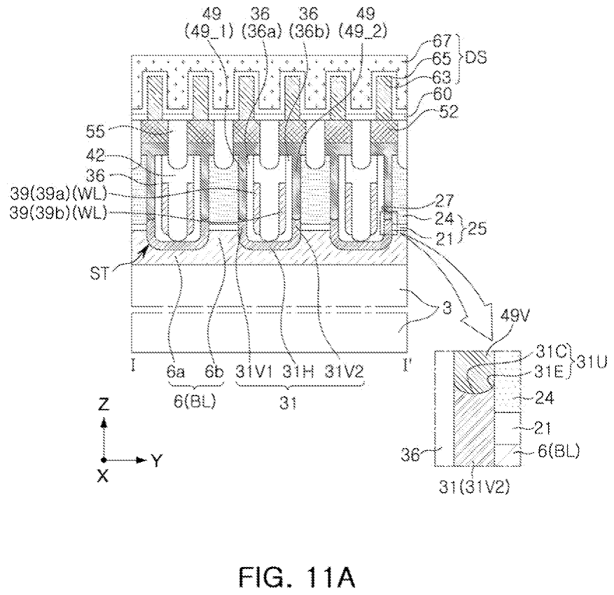

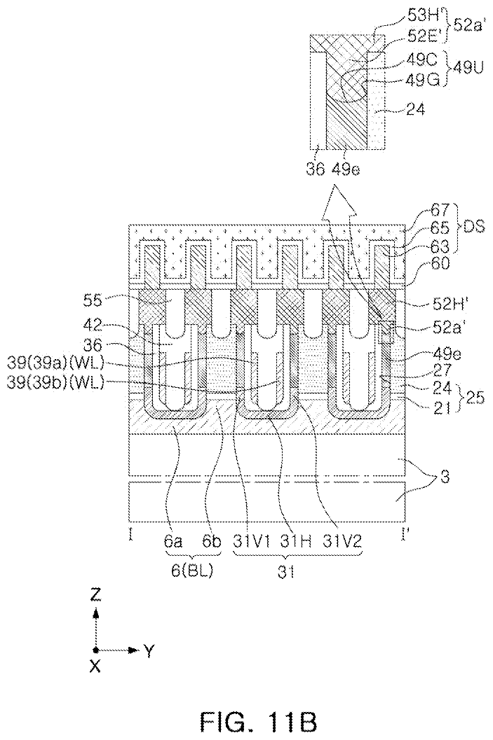

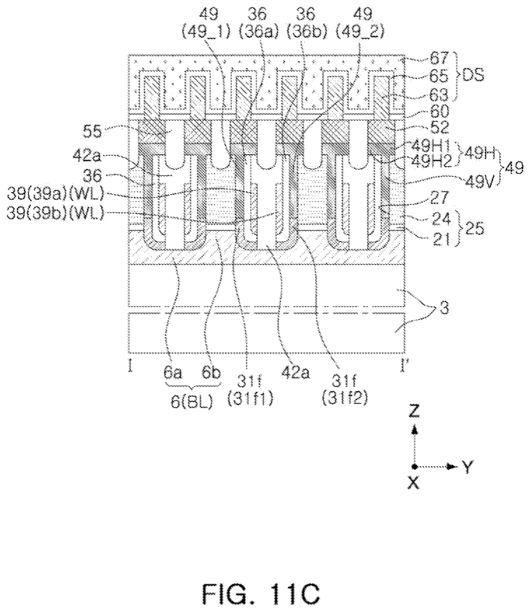

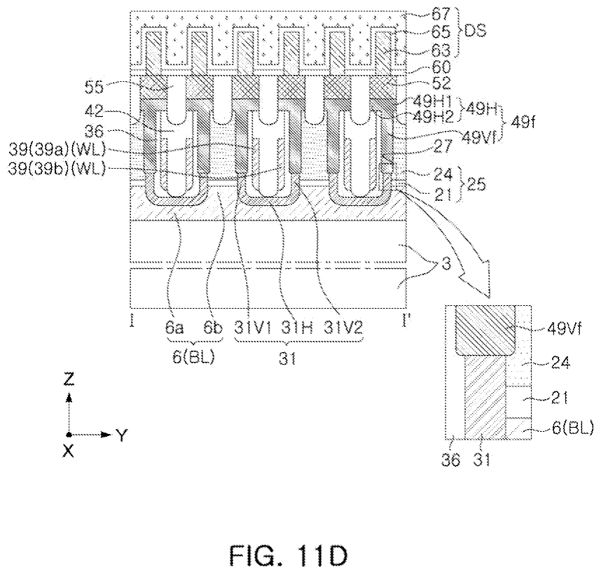

In an implementation, referring to FIG. 11A, the intermediate layers in the example embodiments described above in FIGS. 1 to 10 may instead be an intermediate layer 31e having a curved surface. In an implementation, a surface in contact with the channel layer 49 of the intermediate layer 31 in FIG. 2A may be deformed into a concave shape. In an implementation, an upper surface of the intermediate layer 31 in FIG. 2A contacting the channel layer 49 may instead be a curved upper surface 31U. Accordingly, the intermediate layer 31 in FIG. 2A may instead be an intermediate layer 31e having a curved upper surface 31U.

On the upper surface 31U of the intermediate layer 31e, edge regions 31E may be at a higher level than the middle region 31C.

In an implementation, the upper surface 31U of the intermediate layer 31e may have a curved shape, and a contact area between the intermediate layer 31e and the channel layer 49 may be increased. In an implementation, by increasing the contact area between the intermediate layer 31e and the channel layer 49c, contact resistance between the intermediate layer 31e and the channel layer 49c may be reduced. Accordingly, the electrical characteristics of the semiconductor device may be improved.

In an implementation, referring to FIG. 11B, in the channel layers 49, 49a, 49b, 49c, 49d of the example embodiments of FIGS. 1 to 11A, the extension regions 49H and 49Hc may be omitted, and upper ends of the vertical portions 49V, 49Va, 49Vb, 49Vc, and 49Vd may be lower than a top surface of the insulating structure 25. In an implementation, the channel layer 49 of FIG. 2A may instead be a channel layer 49e having an upper end at a lower level than the upper surface of the insulating structure 25.

Each of the upper conductive patterns 52 and 52a of the example embodiments of FIGS. 1 to 11A may instead be an upper conductive pattern 52a′ including a horizontal portion 52H′ on the upper surface of the insulating structure 25 and an extension portion 52E′ extending downward from the horizontal portion 52H′ and contacting the upper end of the deformed channel layer of the channel layers 49, 49a, 49b, 49c, and 49d of the example embodiments of FIGS. 1 to 11A. In an implementation, the upper surface 49U of the channel layer 48e may be at a lower level than the upper surface of the insulating structure 25, the extension portion 52E′ may be between the interlayer insulating layer 24 and the gate dielectric layer 36 of the insulating structure 25, and the extension portion 52E′ may contact the top surface 49U of the channel layer 48e.

The upper surface 49U of the channel layer 48e may have a curved shape. The upper surface 49U of the channel layer 48e may have a concave shape. On the upper surface 49U of the channel layer 49e, edge regions 49G may be at a higher level than the middle region 49C. In an implementation, the upper surface 49U of the channel layer 49e may have a curved shape, and a contact area between the upper conductive pattern 52a and the channel layer 49e may be increased. In an implementation, by increasing the contact area between the upper conductive pattern 52a and the channel layer 49c, contact resistance between the upper conductive pattern 52a and the channel layer 49c may be reduced. Accordingly, the electrical characteristics of the semiconductor device may be improved.

In an implementation, referring to FIG. 11C, in the example embodiments of FIGS. 1 to 11B, the intermediate insulating pattern 42 may extend downwardly and may instead be an intermediate insulating pattern 42a separating the intermediate layers 31, 31a, 31b, 31c, 31d, and 31e in the first direction Y in the example embodiments of FIGS. 1 to 11B. In an implementation, the intermediate layer 31 in FIG. 2A may instead be an intermediate layer 3 1f including portions 31f1 and 31f2 separated from each other by the intermediate insulating pattern 42a.

In an implementation, referring to FIG. 11D, in the example embodiments of FIGS. 1 to 3 and 5 to 11C, in portions of the channel layer ( 49a, 49b, 49c, 49d, 49e) and the intermediate layer ( 31, 31a, 31c, 31d, 31e) in contact with each other, the channel layers 49a, 49b, 49c, 49d, and 49e may instead be channel layers having a width greater than that of the intermediate layers 31, 31a, 31c, 31d, and 31e.In an implementation, the vertical portion 49V of the channel layer 49a in FIG. 2A may be transformed into a vertical portion 49Vf having a width greater than that of the intermediate layer 31. Accordingly, the channel layer 49 in FIG. 2A may be transformed into a channel layer 49f including the vertical portion 49Vf.

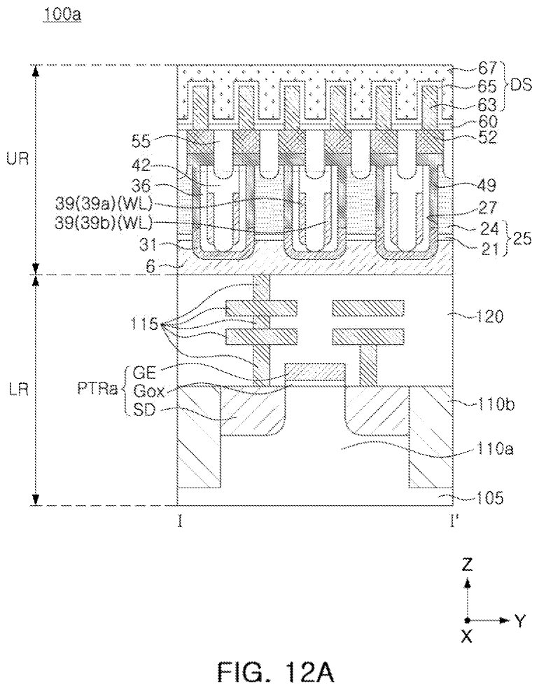

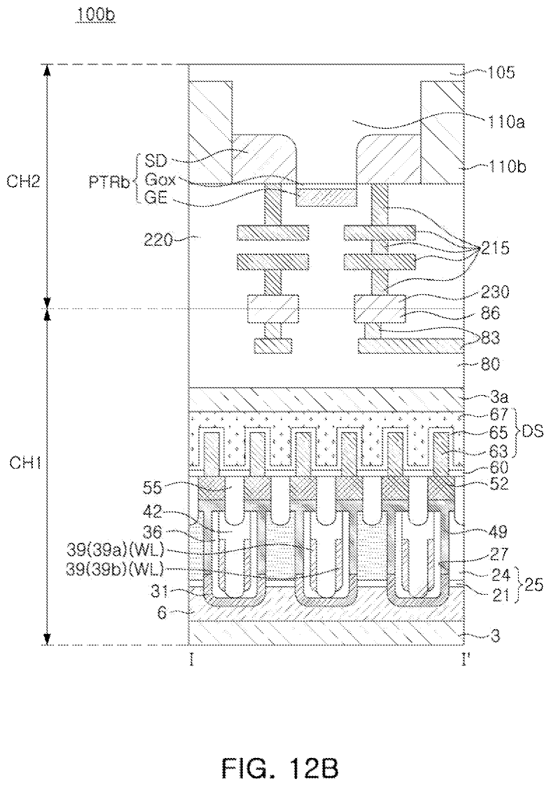

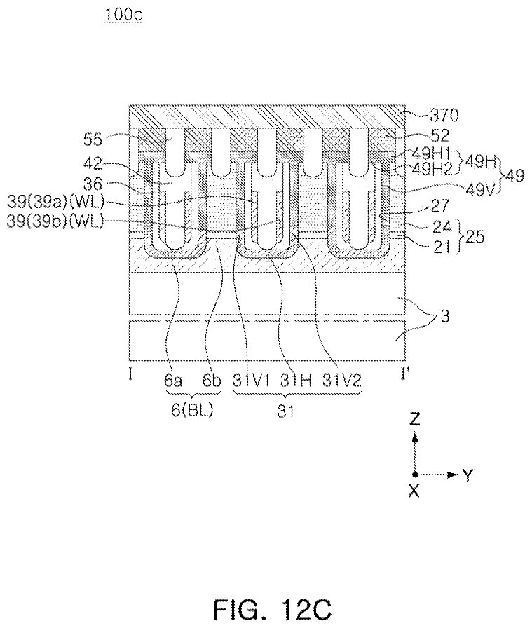

In an implementation, referring to FIG. 12A, in the example embodiments of FIGS. 1 to 11D, the lower structure 3 may instead be a peripheral circuit structure LR including a peripheral circuit. The upper region indicated by “UR” in FIG. 12A may have the same structure as the structure on the lower structure 3 in any one of the example embodiments of FIGS. 1 to 11D, and may be referred to as a memory structure (UR). In an implementation, the upper region indicated by “UR” in FIG. 12A represents the same structure as the structure on the lower structure 3 in FIG. 2A.

The peripheral circuit structure LR may include a semiconductor substrate 105, an active region 110a on the semiconductor substrate 105, an isolation region 110b defining the active region 110a on the semiconductor substrate 105, a peripheral gate (Gox, GE) on the active region 110a, and peripheral sources/drains (SD) in the active region 110a on both sides of the peripheral gates (Gox, GE). The peripheral gates Gox and GE and the peripheral sources/drains SD may constitute the peripheral transistor PTRa. The peripheral gates Gox and GE may include a peripheral gate dielectric layer Gox and a peripheral gate electrode GE sequentially stacked on the active region 110a. The peripheral transistor PTRa may constitute a peripheral circuit.

The peripheral circuit structure LR may further include a peripheral wiring structure 115 electrically connected to the peripheral transistor PTRa, and a peripheral insulating structure 120 covering the peripheral transistor PTRa and the peripheral wiring structure 115 on the semiconductor substrate 105. The peripheral wiring structure 115 may include a vertical portion and a horizontal portion. The peripheral wiring structure 115 may electrically connect the bit line 6 and the peripheral transistor PTRa.

In an implementation, the semiconductor device 100a including the peripheral wiring structure 115 and the memory structure UR may be provided.

In an implementation, referring to FIG. 12B, the semiconductor device in the example embodiments of FIGS. 1 to 11D may instead be a semiconductor device 100b further including an upper insulation structure 80, an upper wiring structure 83 buried in the upper insulating structure 80, lower bonding pads 86 electrically connected to the upper wiring structure 83 and having an upper surface coplanar with an upper surface of the upper insulating structure 80, and an upper chip structure CH2 bonded to the lower bonding pads 86 and the upper insulating structure 80.

The upper insulating structure 80 may be on the data storage structure DS in the example embodiments of FIGS. 1 to 11D. A structure from the lower structure 3 to the upper insulating structure 80 and the lower bonding pads 86 may be defined as a lower chip structure CH1.

The upper chip structure CH2 may include a semiconductor substrate 205, an active region 210a under the semiconductor substrate 205, an isolation region 210b defining the active region 210a under the semiconductor substrate 205, a peripheral gate (Gox, GE) under the active region 10a, ad peripheral sources/drains SD in the active region 210a on both sides of the peripheral gates Gox and GE. The peripheral gates Gox and GE and the peripheral sources/drains SD may constitute the peripheral transistor PTRb. The peripheral gate (Gox, GE) may include a peripheral gate electrode (GE) under the active region 210a and a peripheral gate dielectric layer (Gox) between the active region 210a and the peripheral gate electrode (GE). The peripheral transistor PTRb may constitute a peripheral circuit.

The upper chip structure CH2 may further include a peripheral wiring structure 215 electrically connected to the peripheral transistor PTRb under the semiconductor substrate 205, and a peripheral insulating structure 220 covering the peripheral transistor PTRb and the peripheral wiring structure 215 under the semiconductor substrate 205. The peripheral wiring structure 215 may include a vertical portion and a horizontal portion. The peripheral wiring structure 215 may electrically connect the bit line 6 and the peripheral transistor PTRa.

The upper chip structure CH2 may further include an upper bonding pad 230 electrically connected to the peripheral wiring structure 215 and side surfaces covered by the peripheral insulating structure 220.

The peripheral insulating structure 220 may contact the upper insulating structure 80, and the upper bonding pad 230 may contact and bond to the lower bonding pad 86. The upper bonding pad 230 and the lower bonding pad 86 may include the same metal material as each other, e.g., copper (Cu).

In an implementation, referring to FIG. 12C, in the example embodiments of FIGS. 1 to 12B, the data storage structure DS may be omitted, and the gate dielectric layers 36 may instead be information storage layers 336 capable of storing information. Each of the data storage layers 336 may include a ferroelectric layer capable of storing information. The ferroelectric layer capable of storing information may have polarization characteristics according to the electric field applied by the word lines 39, and may have remnant polarization due to dipoles even in the absence of an external electric field. Data may be recorded using the polarization state in the ferroelectric layer of the data storage layers 336.

The ferroelectric layer of the data storage layers 336 may include an Hf compound, a Zr compound, or a Hf—Zr compound. In an implementation, the Hf compound may include a HfO ferroelectric material, the Zr compound may include a ZrO ferroelectric material, and the Hf—Zr compound may include a hafnium zirconium oxide (HZO) ferroelectric material. The ferroelectric layer of the data storage layers 336 may include impurities, e.g., a ferroelectric material doped with C, Si, Mg, Al, Y, N, Ge, and Sn, Gd, La, Sc, or Sr., in the data storage layers 336, the ferroelectric layer may be a material in which HfO₂, ZrO₂, or HZO is doped with C, Si, Mg, Al, Y, N, Ge, Sn, Gd, La, Sc, or Sr. In an implementation, the ferroelectric layer of the data storage layers 336 may contain a suitable material with ferroelectric properties capable of storing information.

Each of the data storage layers 336 may have a structure in which lower dielectric layers and ferroelectric layers are alternately laminated. In an implementation, the lower dielectric layer may include silicon oxide, silicon oxynitride, silicon nitride, or a high-K dielectric. The high-K dielectric may include a metal oxide or a metal oxynitride. In an implementation, the high dielectric may include HfO₂, HfSiO, HfSiON, HfTaO, HfTiO, HfZrO, ZrO₂, Al₂O₃, or combinations thereof.

In an implementation, a semiconductor device 100c including the data storage layers 336 may be provided.

The semiconductor device 100c may further include an upper conductive line 370 on the upper conductive patterns, e.g., the upper conductive patterns 52 of FIG. 2A in the example embodiments of FIGS. 1 to 12B. The upper conductive line 370 may be electrically connected to the upper conductive patterns 52. The upper conductive line 370 may vertically overlap the bit line 6. The upper conductive line 370 may be a source line.

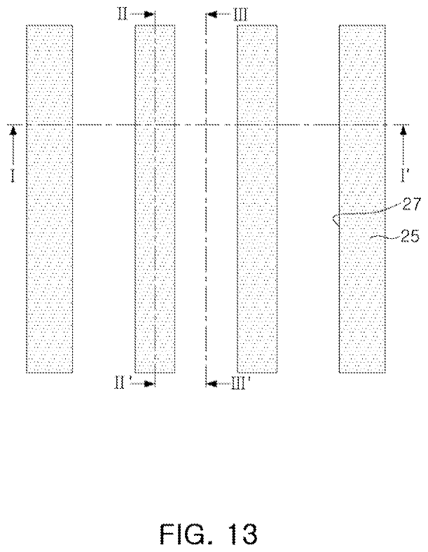

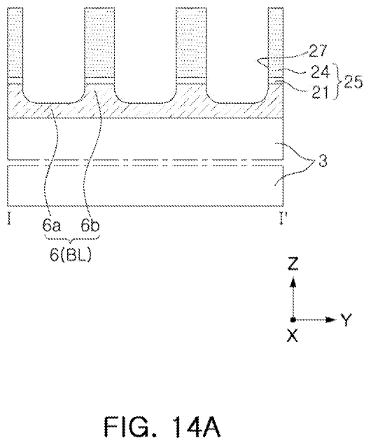

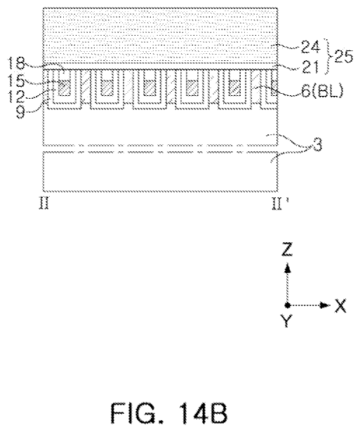

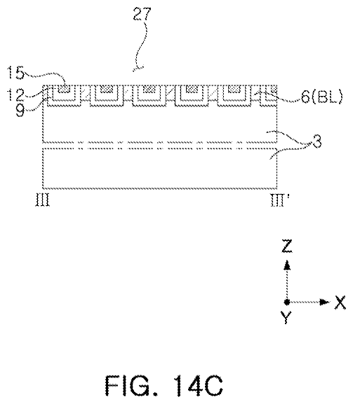

Hereinafter, illustrative examples of a method of forming a semiconductor device according to embodiments will be described with reference to FIGS. 13 to 23C. In FIGS. 13 to 23C, FIGS. 13, 15, 17, and 19 are plan views of stages in a method of forming a semiconductor device according to example embodiments, FIGS. 14A, 16A, 18A, 20, 21, 22, and 23A are cross-sectional views schematically illustrating a region taken along line I-I′ of FIG. 1, FIGS. 14B, 16B, 18B, and 23B are cross-sectional views schematically illustrating a region taken along line II-II′ in FIG. 1, FIGS. 14C, 16C, 18C, and 23C are cross-sectional views schematically illustrating a region taken along line III-III′ in FIG. 1.

In FIGS. 13, 14A, 14B and 14C, a lower structure 3 may be formed. First conductive lines 6 may be formed on the lower structure 3. Each of the first conductive lines 6 may have a linear shape extending in the first direction Y. The first conductive lines 6 may be spaced apart from each other in a second direction X perpendicular to the first direction Y. The first conductive lines 6 may be bit lines BL.

Shield structures 8 may be formed between the first conductive lines 6. Each of the shield structures 8 may include a conductive shield pattern 15, a first insulating layer 9 covering the side surface and the bottom surface of the conductive shield pattern 15, a second insulating layer 12 between the first insulating layer 9 and the conductive shield pattern 15, and a third insulating layer 18 on the conductive shield pattern 15.

An insulating structure 25 having an opening 27 may be formed on the conductive lines 6 and the shield structures 8. The insulating structure 25 may include an etch stop layer 21 and an interlayer insulating layer 24 sequentially stacked.

Forming the insulating structure 25 may include forming the etch stop layer 21 and the interlayer insulating layer 24 sequentially stacked, and patterning the etch stop layer 21 and the interlayer insulating layer 24 to form the opening 27. While forming the opening 27, the thickness of the first conductive lines 6 exposed by the opening 27 may decrease. In an implementation, each of the first conductive lines 6 may include a first region 6a having a reduced thickness by the opening 27, and a second region 6b vertically overlapping the insulating structure 25.

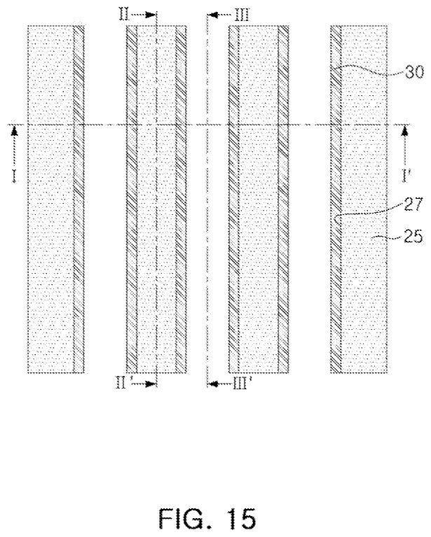

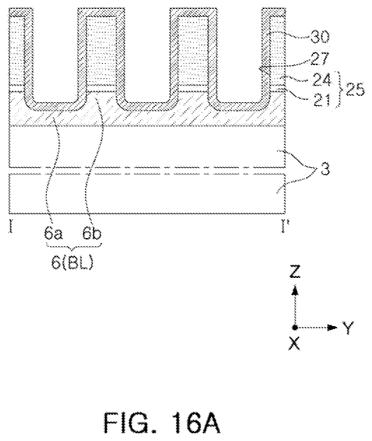

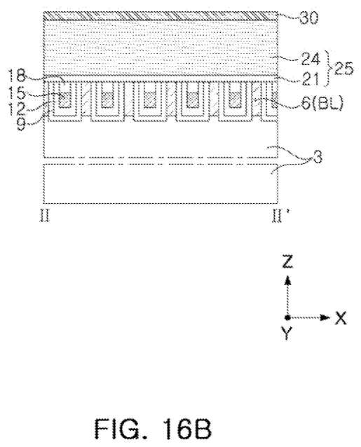

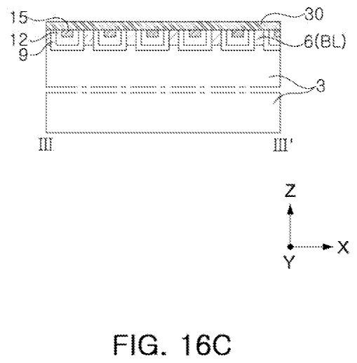

Referring to FIGS. 15, 16A, 16B, and 16C, a preliminary intermediate layer 30 conformally covering the sidewall and the bottom surface of the opening 27 and the top surface of the insulating structure 25 may be formed.

In an implementation, the preliminary intermediate layer 30 may be formed of a conductive material.

In an implementation, the preliminary intermediate layer 30 may be formed of an insulating material.

In an implementation, the preliminary intermediate layer 30 may be formed of a conductive material layer and an insulating material layer sequentially stacked.

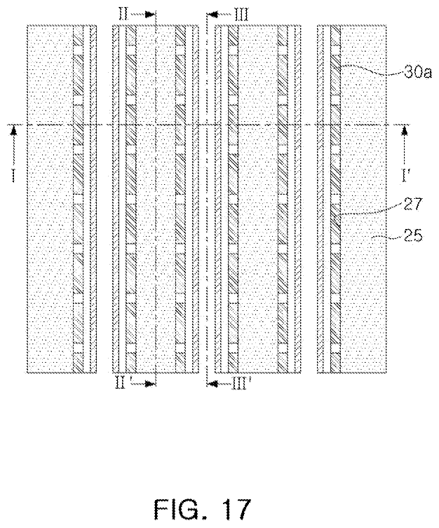

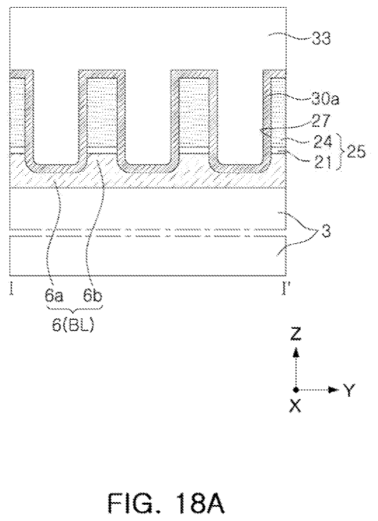

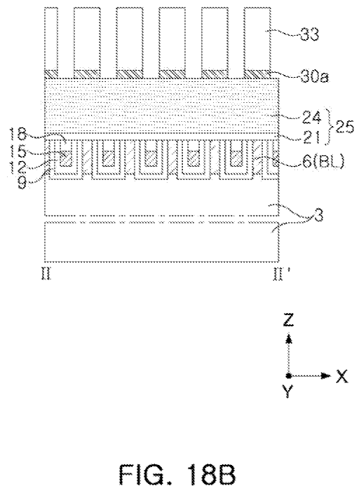

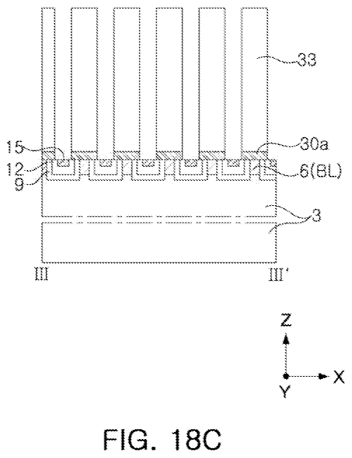

Referring to FIGS. 17, 18A, 18B, and 18C, mask patterns 33 may be formed on the preliminary intermediate layer 30. Each of the mask patterns 33 may have a line shape extending in the first direction Y.

The preliminary intermediate layer 30 may be etched in an etching process using the mask patterns 33 as an etching mask to form preliminary intermediate patterns 30a. The preliminary intermediate patterns 30a may be spaced apart from each other in the second direction X.

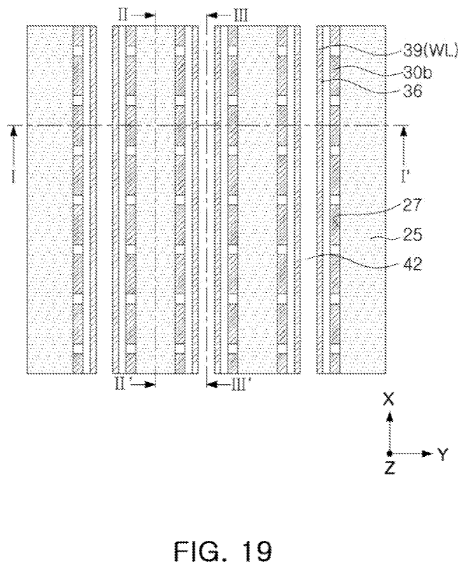

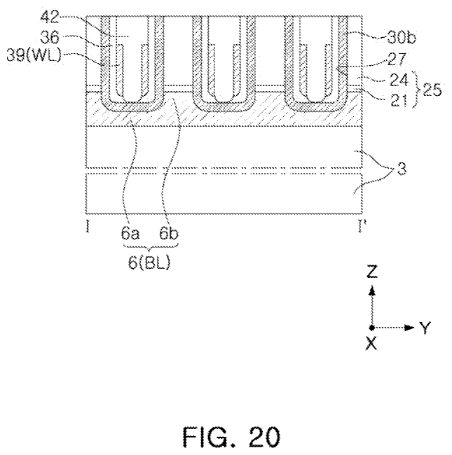

Referring to FIGS. 19 and 20, the mask patterns 33 may be removed. A gate dielectric layer 36 may be formed to cover the preliminary intermediate patterns 30a.

A conformal conductive layer may be formed on the gate dielectric layer 36, and the conductive layer may be etched to form second conductive lines 39. The second conductive lines 39 may be word lines WL.

The second conductive lines 39 may be formed in the opening 27, and may have upper surfaces positioned at a level lower than the upper surface of the insulating structure 25.

The insulating material layer is formed and may then be planarized until the upper surface of the insulating structure 25 is exposed. In an implementation, an intermediate insulating pattern 42 remaining in the opening 27 and covering the second conductive lines 39 may be formed, and the preliminary intermediate patterns 30a may remain in the opening 27. Upper surfaces of the preliminary intermediate patterns 30a remaining in the opening 27 may be exposed.

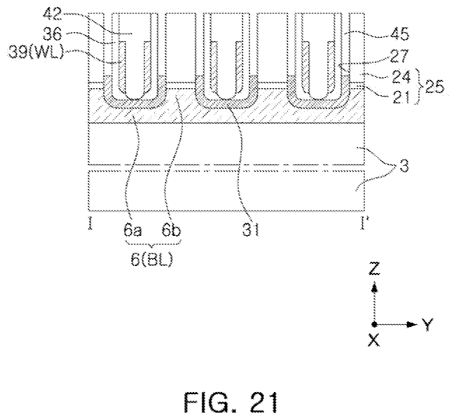

Referring to FIG. 21, an intermediate layer 31 may be formed by etching at least a portion of the preliminary intermediate patterns 30a. According to the amount by which the preliminary intermediate patterns 30a are etched, the preliminary intermediate patterns 30a may be formed of any one intermediate layer among the intermediate layers 31, 31a, 31c, 31d, and 31e of various embodiments described above. FIG. 21 illustrates the intermediate layer 31 as in FIG. 2A.

Empty spaces 45 may be formed by etching the preliminary intermediate patterns 30a. In an implementation, when the intermediate layer 31 as in FIG. 2A is formed, the empty spaces 45 may be formed between the gate dielectric layer 36 and the insulating structure 25.

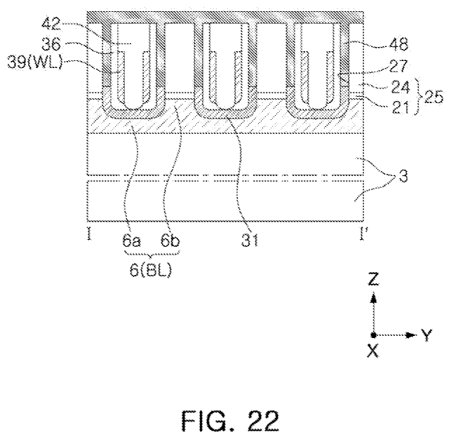

Referring to FIG. 22, a preliminary channel layer 48 may be formed to cover the upper surface of the insulating structure 25 while filling the empty spaces 45.

In an implementation, in the case of the pre-channel layer 48, to form the channel layers 49c and 49d as in FIGS. 7 to 10, the preliminary channel layer 48 may be formed to partially fill the empty spaces 45 while conformally covering the bottom and side surfaces of each of the empty spaces 45. The remaining spaces of the empty spaces 45 not filled by the preliminary channel layer 48 may be filled with an insulating material, or may be left as an empty space.

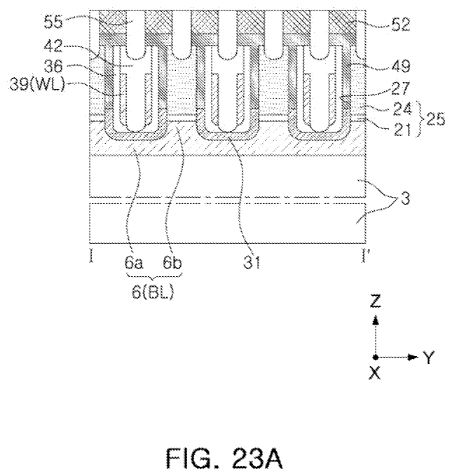

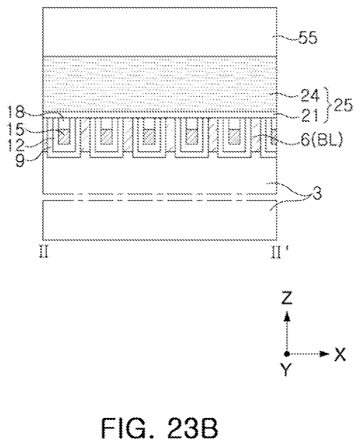

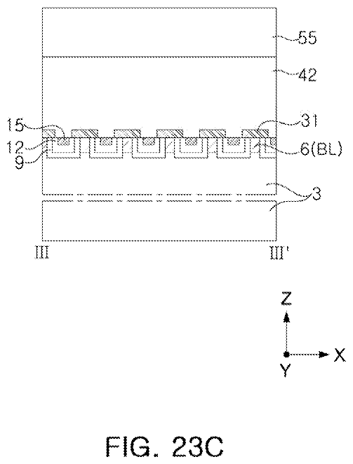

Referring to FIGS. 23A, 23B, and 23C, by forming a conductive layer on the preliminary channel layer 48 and patterning the conductive layer and the preliminary channel layer 48, upper conductive patterns 52 and channel layers 49 may be formed. Accordingly, the upper conductive patterns 52 may be vertically aligned with the remaining channel layers 49 on the upper surface of the insulating structure 25. The channel layers 49 remaining on the upper surface of the insulating structure 25 may be referred to as the extension portions (49H of FIG. 2A) as in FIG. 2A and described.

Then, an insulating material layer covering the upper surfaces and side surfaces of the upper conductive patterns 52 may be formed, and the insulating material layer may be planarized until top surfaces of the upper conductive patterns 52 are exposed, thereby forming an insulating separation pattern 55.

Referring again to FIGS. 1, 2A, 2B and 2C, an etch stop layer 60 may be formed on the upper conductive patterns 52 and the insulating separation pattern 55. The etch stop layer 60 may be formed of an insulating material, e.g., silicon nitride, SiBN, SiCN, or an insulating metal oxide. A data storage structure DS electrically connected to the upper conductive patterns 52 may be formed. The data storage structure DS may include first electrodes 63 penetrating the etch stop layer 60 and electrically connected to the upper conductive patterns 52, a dielectric layer 65 covering the first electrodes 63 and the etch stop layer 60, and a second electrode 67 covering the dielectric layer 65.

By way of summation and review, in DRAM, reliably and stably forming size-reduced elements has been considered. The distribution characteristics of semiconductor devices could be degraded as the size of elements is reduced.

As set forth above, according to example embodiments, a method of forming upper conductive patterns and channel layers may be provided by forming preliminary intermediate patterns in a “U” shape in the opening of an insulating structure, etching at least a portion of the preliminary intermediate patterns to form empty spaces, forming preliminary channel layers covering the upper surface of the insulating structure while being formed in the empty spaces, forming a conductive layer on the preliminary channel layers, and simultaneously patterning the conductive layer and the preliminary channel layer. The channel layers formed by this method may include vertical portions remaining in the empty spaces in the openings, and extension portions remaining on the upper surface of the insulating structure. The extension portions and the upper conductive patterns may be vertically aligned. The preliminary intermediate patterns may remain in the openings and be formed as intermediate layers. The preliminary intermediate patterns may be spaced apart from each other in a longitudinal direction of the opening. Accordingly, the channel layers may be spaced apart in a longitudinal direction of the opening.

According to an example embodiment, the vertical portions of the channel layers spaced apart in the longitudinal direction of the opening within the opening may be formed by filling the empty spaces without a separate etching process. Therefore, in the case of forming the channel layers with an oxide semiconductor, since the vertical portions of the channel layers spaced apart in the longitudinal direction of the opening may be formed without etching the oxide semiconductor layer positioned on the side surface of the opening, reliable channel layers may be provided.

One or more embodiments may provide a semiconductor device in which reliability may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a bit line extending in a first direction;
a word line extending in a second direction crossing the first direction, the word line being at a level higher than a level of the bit line;
a channel layer on the bit line, the channel layer including a vertical portion at least partially at the same level as the word line, and an extension portion extending from an upper region of the vertical portion;
a gate dielectric layer at least partially between the vertical portion and the word line; and
an upper conductive pattern on the extension portion,
wherein:
the extension portion includes a first region vertically overlapping the vertical portion and a second region not vertically overlapping the vertical portion, and
the upper conductive pattern has a side surface vertically aligned with a side surface of the extension portion.

2. The semiconductor device as claimed in claim 1, further comprising an intermediate layer between the channel layer and the bit line,
wherein the intermediate layer is in contact with the bit line and the channel layer.

3. The semiconductor device as claimed in claim 2, wherein an upper end of the intermediate layer is at a level higher than a level of a lower end of the word line.

4. The semiconductor device as claimed in claim 2, wherein:
the intermediate layer includes an intermediate portion vertically overlapping the vertical portion, and a connection portion extending from a lower region of the intermediate portion and not overlapping the vertical portion, and
the connection portion is in contact with the bit line.

5. The semiconductor device as claimed in claim 4, wherein:
the bit line has a first upper surface and a second upper surface at a level lower than the first upper surface, and
the second upper surface of the bit line is in contact with the connection portion of the intermediate layer.

6. The semiconductor device as claimed in claim 2, wherein the intermediate layer includes a conductive material layer or an insulating material layer.

7. The semiconductor device as claimed in claim 2, wherein:
the intermediate layer includes a conductive material layer and an insulating material layer on the conductive material layer,
the conductive material layer is in contact with the bit line and the channel layer, and
the insulating material layer is in contact with the gate dielectric layer.

8. The semiconductor device as claimed in claim 1, wherein the extension portion of the channel layer includes a region vertically overlapping the gate dielectric layer and the word line.

9. The semiconductor device as claimed in claim 8, wherein the extension portion of the channel layer is in contact with the gate dielectric layer.

10. The semiconductor device as claimed in claim 1, wherein the channel layer is in contact with the bit line.

11. The semiconductor device as claimed in claim 1, further comprising an intermediate layer at least partially between a lower surface of the word line and the bit line,
wherein the gate dielectric layer extends between the lower surface of the word line and the intermediate layer from a portion disposed between the vertical portion and the word line.

12. A semiconductor device, comprising:
a bit line;
a first channel layer and a second channel layer spaced apart from each other on the bit line;
a first word line and a second word line spaced apart from each other on the bit line, and respectively including a portion between the first and second channel layers;
an intermediate layer connected to the first and second channel layers and the bit line;
a first gate dielectric layer at least partially between the first channel layer and the first word line;
a second gate dielectric layer at least partially between the second channel layer and the second word line;
a first upper conductive pattern on the first channel layer and connected to the first channel layer; and
a second upper conductive pattern on the second channel layer and connected to the second channel layer.

13. The semiconductor device as claimed in claim 12, wherein the intermediate layer includes:
a first intermediate portion vertically overlapping the first channel layer;
a second intermediate portion vertically overlapping the second channel layer; and
a connection portion extending from lower regions of the first and second intermediate portions and contacting the bit line.

14. The semiconductor device as claimed in claim 13, wherein the connection portion vertically overlaps the first word line and the second word line.

15. The semiconductor device as claimed in claim 12, wherein the intermediate layer includes a conductive material layer.

16. The semiconductor device as claimed in claim 12, wherein:
an upper end of the intermediate layer is at a level higher than a level of a lower end of the first word line, and
the upper end of the intermediate layer is at a level higher than a level of a lower end of the second word line.

17. The semiconductor device as claimed in claim 12, wherein:
each of the first channel layer and the second channel layer includes a vertical portion and an extension portion extending from an upper region of the vertical portion,
the extension portion of the first channel layer vertically overlaps the first word line, and
the extension portion of the second channel layer vertically overlaps the second word line.

18. A semiconductor device, comprising:
a bit line;
an insulating structure on the bit line and having an opening exposing the bit line;
a structure at least partially in the opening; and
upper conductive patterns on the structure,
wherein:
the structure includes:
a first channel layer and a second channel layer spaced apart from each other in the opening;
a first word line and a second word line spaced apart from each other in the opening and respectively including a portion between the first and second channel layers;
an intermediate insulating pattern in the opening and between the first and second word lines and covering upper surfaces of the first and second word lines;
a first gate dielectric layer at least partially between the first channel layer and the first word line; and
a second gate dielectric layer at least partially between the second channel layer and the second word line,
each of the first and second channel layers includes a vertical portion in the opening and an extension portion extending from an upper region of the vertical portion,
the upper conductive patterns include a first upper conductive pattern on the extension portion of the first channel layer and a second upper conductive pattern on the extension portion of the second channel layer,
the first upper conductive pattern has a side surface vertically aligned with a side surface of the extension portion of the first channel layer, and
the second upper conductive pattern has a side surface vertically aligned with a side surface of the extension portion of the second channel layer.

19. The semiconductor device as claimed in claim 18, further comprising an intermediate material layer in contact with the first and second channel layers and the bit line, wherein:
the intermediate material layer includes intermediate portions vertically overlapping the vertical portions of the first and second channel layers, and a connection portion extending from lower regions of the intermediate portions, and
the connection portion of the intermediate material layer vertically overlaps the first and second word lines.

20. The semiconductor device as claimed in claim 19, wherein:
the first and second channel layers each include an oxide semiconductor, and the intermediate material layer includes TiN.
